(19) United States
(12) Patent Application Publication
(10) Pub. No.: US 2026/0343928 A1
(43) Pub. Date: Oct. 29, 2026

(54) POLYSILICON CARBIDE SUBSTRATE FOR DOUBLE GATE GALLIUM NITRIDE (GaN) HIGH ELECTRON MOBILITY TRANSISTOR (HEMT) AND METHOD FOR MAKING SAME

(71) Applicant: Microchip Technology Incorporated, Chandler, AZ (US)

(72) Inventors: Steve Nagel, Chandler, AZ (US); Bomy Chen, Newark, CA (US)

(21) Appl. No.: 19/559,600

(22) Filed: Mar. 6, 2026

Related U.S. Application Data
(60) Provisional application No. 63/793,144, filed on Apr. 23, 2025.

(51) Int. Cl. H10D 30/47; H10D 30/01; H10D 62/824; H10P 14/20; H10P 90/00; H10W 10/10

(52) U.S. Cl. CPC H10D 30/474; H10D 30/015; H10D 30/023; H10D 62/824; H10P 14/3802; H10P 90/1914; H10W 10/181

(57) ABSTRACT

A method of forming a semiconductor device is provided. The method may include patterning a bottom gate area in a poly-silicon carbide (pSiC) substrate, depositing gate material in the bottom gate area to form a bottom gate terminal, planarizing the gate material, bonding a gallium nitride (GaN) wafer to the pSiC substrate, and forming a source terminal, a drain terminal, and a top gate terminal in the GaN wafer.

### CROSS-REFERENCE TO RELATED APPLICATION

The present application claims priority from U.S. Provisional Patent Application No. 63/793,144, filed on Apr. 23, 2025, which is incorporated herein by reference in its entirety.

### TECHNICAL FIELD

The present disclosure relates generally to high electron mobility transistors (HEMTs), and more specifically to a polysilicon carbide substrate for double gate gallium nitride (GaN) HEMTs, and a method for making same.

### BACKGROUND

Gallium nitride (GaN) is a leading candidate for high electron mobility transistors (HEMTs), particularly for future high frequency switching applications. However, many GaN HEMTs use a single crystal silicon (Si) or silicon carbide (SiC) substrate, which significantly increases cost. In addition, Si substrates also suffer from high Eddy currents. Therefore, there is a need for a less expensive, potentially higher performance device with low Eddy currents.

### SUMMARY

According to an aspect of one or more examples, there is provided a method of forming a semiconductor device. The method may include patterning a bottom gate area in a poly-silicon carbide (pSiC) substrate, depositing gate material in the bottom gate area to form a bottom gate terminal, planarizing the gate material, bonding a gallium nitride (GaN) wafer to the pSiC substrate, and forming a source terminal, a drain terminal, and a top gate terminal in the GaN wafer. The method may include depositing an insulator material in the bottom gate area before depositing the gate material. The GaN wafer may include a dual GaN channel formed on a first aluminum gallium nitride (AlGaN) layer. The dual GaN channel may be a single crystal layer, and the first AlGaN layer may be a single crystal layer.

The method may include forming a second AlGaN layer on a side of the dual GaN channel opposite the first AlGaN layer, forming a first insulator layer on the second AlGaN layer, forming an aluminum oxide (AlO) layer on the first insulator layer, and forming a second insulator layer on the AlO layer. The top gate terminal may be formed in contact with the AlO layer. The method may include performing a hot press process after the GaN wafer is bonded to the pSiC substrate to cause crystallization of at least a portion of the pSiC substrate.

According to an aspect of one or more examples, there is provided a method of forming a semiconductor device. The method may include etching a mandrel pattern in a wafer, forming a pSiC substrate on the wafer, removing the wafer to expose a mandrel opening in a first side of the pSiC substrate corresponding to the mandrel pattern, patterning a bottom gate area in a second side of the pSiC substrate opposite the mandrel opening in the first side of the pSiC substrate, depositing gate material in the bottom gate area to form a bottom gate terminal, planarizing the gate material, bonding a GaN wafer to the pSiC substrate, and forming a source terminal, a drain terminal, and a top gate terminal in the GaN wafer. The method may include forming a liner to line the mandrel opening in the first side of the pSiC substrate. The liner may be made of nickel or titanium. The method may include inserting a metal paste into the mandrel opening in the first side of the pSiC substrate. The GaN wafer may include a dual GaN channel formed on a first AlGaN layer. The dual GaN channel may be a single crystal layer, and the first AlGaN layer may be a single crystal layer. The method may include forming the pSiC substrate by performing a hot press process on first AlGaN layer bonded to a pSiC substrate to cause crystallization of at least a portion of the pSiC substrate.

According to an aspect of one or more examples, there is provided a semiconductor device, which may include a pSiC substrate having a bottom gate terminal in a first side therein, and a GaN wafer in contact with the pSiC substrate. The GaN wafer may include a source terminal, a drain terminal, and a top gate terminal. The GaN wafer may include a dual GaN channel on a first AlGaN layer. The dual GaN channel may be a single crystal layer, and the first AlGaN layer may be a single crystal layer. The pSiC substrate may include a crystallized portion adjacent to the GaN wafer. The semiconductor device may include a mandrel opening in a second side of the PSiC substrate opposite the bottom gate terminal, a metal paste within the mandrel opening, and a liner to line the mandrel opening.

According to an aspect of one or more examples, there is provided a vertical semiconductor device, which may include a pSiC substrate having a mandrel opening at a first side of the pSiC substrate, a drain terminal at a bottom portion of the mandrel opening, and a GaN wafer in contact with a second side of the pSiC substrate. The GaN wafer may include a first source terminal, a second source terminal, a first top gate and a first bottom gate to control current flow from the first source terminal, and a second top gate and a second bottom gate to control current flow from the second source terminal. The vertical semiconductor device may include a liner to line the mandrel opening, and a metal paste within the mandrel opening. The pSiC substrate may include a crystallized portion adjacent to the GaN wafer. The GaN wafer may include a dual GaN channel that is a single crystal layer.

### BRIEF DESCRIPTION OF DRAWINGS

FIG. 1 shows a semiconductor device according to various examples.

FIG. 2 shows a semiconductor device according to various examples.

FIGS. 3A and 3B show a pSiC substrate before and after undergoing a hot press process, respectively, according to various examples.

FIG. 4 shows iterative stages of a semiconductor device during a method of forming the semiconductor device according to various examples.

FIG. 5 shows iterative stages of a semiconductor device during a method of forming the semiconductor device according to various examples.

FIG. 6 shows a vertical semiconductor device according to various examples.

FIG. 7 shows a method of forming a semiconductor device according to various examples.

FIG. 8 shows a method of forming a semiconductor device according to various examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

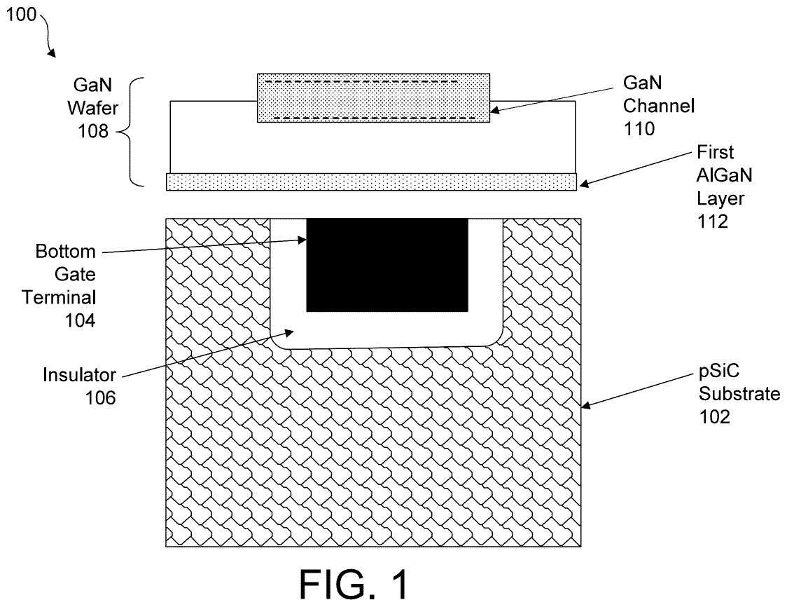

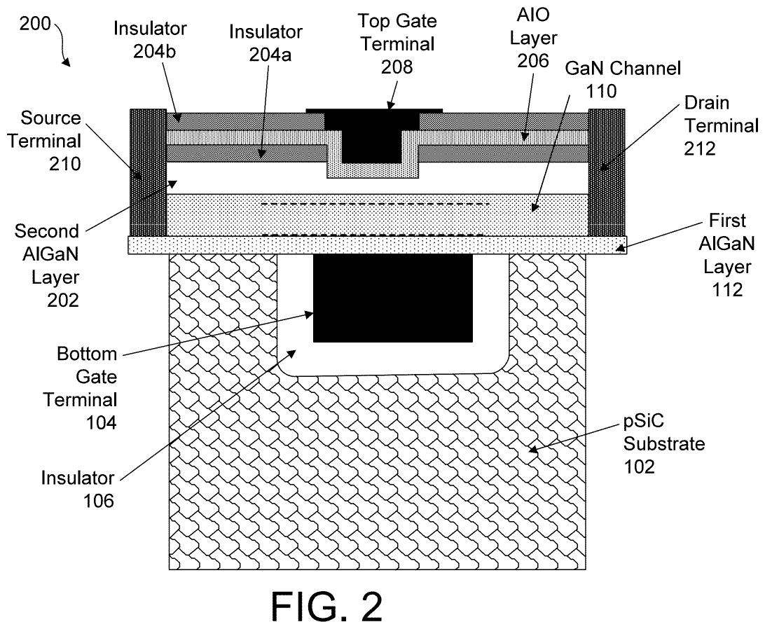

FIGS. 1 and 2 show block diagrams of semiconductor devices 100 and 200, respectively, according to various examples. Referring to FIG. 1, a semiconductor device 100 may include a poly-silicon carbide (pSiC) substrate 102. A bottom gate area may be patterned into the pSiC substrate 102 for formation of a bottom gate terminal 104, for example by etching a portion of the pSiC substrate 102. According to one or more examples, after the bottom gate area is patterned, an insulator material 106, such as silicon nitride (SiN), may be formed in the bottom gate area. A gate material, such as p-type GaN, may be deposited in the bottom gate area to form the bottom gate terminal 104. The gate material may be planarized to form a substantially flat upper surface with the pSiC substrate 102.

A GaN wafer 108 may be bonded to the pSiC substrate 102. The GaN wafer 108 may include a GaN channel 110 and a first aluminum gallium nitride (AlGaN) layer 112. The GaN channel 110 and the first AlGaN layer 112 may be hydrogen cut and bonded to the pSiC substrate 102. According to various examples, the GaN channel 110 may be a dual channel (shown as dashed lines) conducting current from a source terminal to a drain terminal, such as shown in FIG. 2 with respect to source terminal 210 and drain terminal 212. The GaN channel 110 may be a single crystal, and the first AlGaN layer 112 may be a single crystal layer.

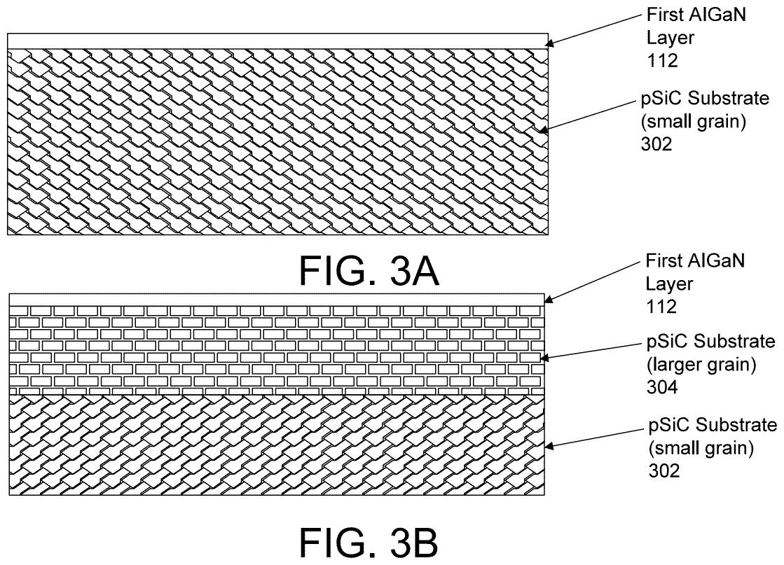

According to various examples, the bonded GaN wafer 108 and pSiC substrate 102 may undergo a hot press process, which may cause a layer of the pSiC 102 to reorganize in a crystalline pattern (i.e., neo-crystallization) from the first AlGaN layer 112 that was bonded to the pSiC substrate 102. For example, the hot press process may be a ceramic isostatic process using high temperature and high-pressure process. As shown in FIGS. 3A and 3B, the hot press process may cause a portion of the pSiC substrate 302, which is a small grain structure, to reorganize into a larger grain structure 304 that may be more similar to single crystal SiC. Therefore, the hot press process may allow the pSiC substrate 102 to achieve similar performance and function as single crystal SiC at a lower cost.

Referring again to FIG. 2, the method may include forming a second AlGaN layer 202 on a side of the GaN channel 110 opposite the first AlGaN layer 112. The method may include forming a first insulator layer 204a on the second AlGaN layer 202, forming an aluminum oxide (AlO) layer 206 on the first insulator layer 204a, and forming a second insulator layer 204b on the AlO layer 206. The method may include forming a top gate terminal 208 in the AlO layer 206. For example, the method may include an etching operation to etch the second insulator layer 204b so that the top gate terminal 208 may be formed in contact with the AlO layer 206.

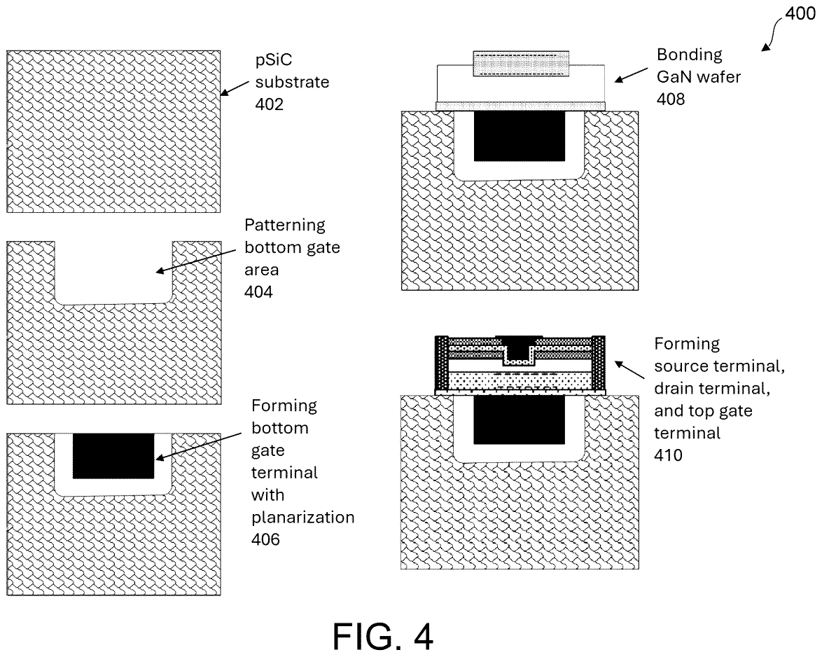

FIG. 4 shows iterative stages of a semiconductor device 400 during a method of forming a semiconductor device according to various examples. The method may include operations performed on a pSiC substrate, such as pSiC substrate 402. pSiC substrate 402 can be further understood as pSiC substrate 102. The method may include patterning a bottom gate area 404 in pSiC substrate 402. The patterning can be achieved through etching a portion of pSiC substrate 402. The method may include depositing gate material in the bottom gate area to form a bottom gate terminal, such as bottom gate terminal 406. The gate material can be a p-type GaN, without limitation. The gate material can be planarized to form a substantially flat upper surface. In some aspects, after the bottom gate area is patterned, an insulator material, such as SiN, may be formed in the bottom gate area before depositing gate material. The method may include bonding a GaN wafer 408 to the pSiC substrate 402. GaN wafer 408 can be further understood as GaN wafer 108. The GaN wafer 408 may include a GaN channel and a first AlGaN layer. The GaN channel and the first AlGaN layer may be hydrogen cut and bonded to the pSiC substrate 402. According to various examples, the GaN channel may be a dual GaN channel formed on the first AlGaN layer, conducting current from a source terminal to a drain terminal. The dual GaN channel may be a single crystal, and the first AlGaN layer may be a single crystal layer. The method may include forming the source terminal, the drain terminal, and a top gate terminal 410 on GaN wafer 408.

The bonded GaN wafer 408 and pSiC substrate 402 may undergo a hot press process, which may cause a layer of the pSiC substrate 402 to reorganize in a crystalline pattern (i.e., neo-crystallization) from the first AlGaN layer that was bonded to the pSiC substrate 402. As discussed in connection with FIG. 2 and as shown in forming the source terminal, drain terminal, and top gate terminal 410, the method of forming semiconductor device 400 may include forming a second AlGaN layer on a side of the GaN channel opposite the first AlGaN layer. The method may include forming a first insulator layer on the second AlGaN layer, forming an AlO layer on the first insulator layer, and forming a second insulator layer on the AlO layer. The method may include forming a top gate terminal in the AlO layer.

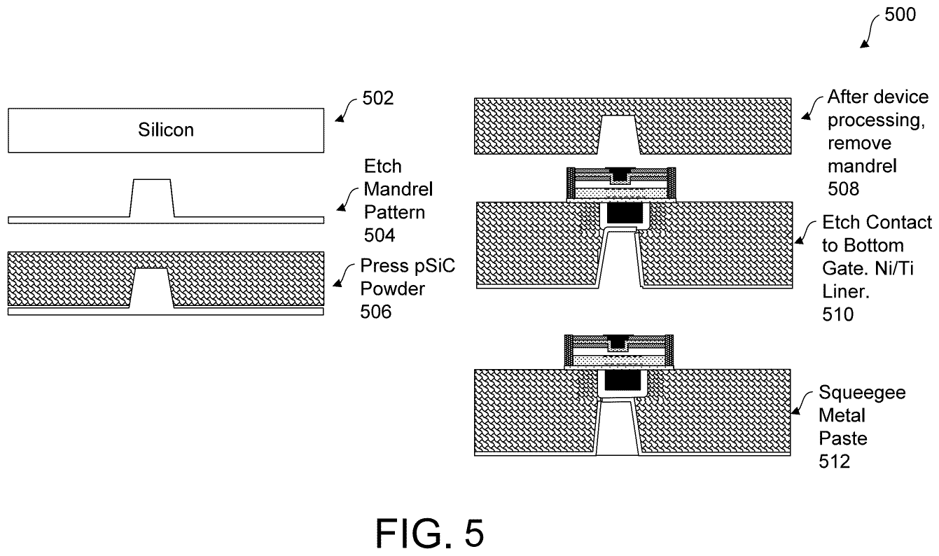

FIG. 5 shows iterative stages of a semiconductor device 500 during a method of forming the semiconductor device 500 according to various examples. The method may include etching a mandrel pattern in a wafer 504, such as a silicon wafer 502, without limitation. The mandrel pattern 504 may be substantially trapezoidal in shape, though other shapes may be used. The method may include forming a pSiC substrate on the wafer 506. For example, the pSiC substrate may be formed by pressing a pSiC powder. After the pSiC substrate is formed, the wafer may be removed to expose a mandrel opening in a first side of the pSiC substrate 508. The method may include patterning a bottom gate area in a second side of the pSiC substrate opposite the mandrel opening in the first side of the pSiC substrate. The method may include depositing gate material in the bottom gate area and planarizing the gate material to form a bottom gate terminal. The method may include bonding a GaN wafer to the pSiC substrate, and forming a source terminal, a drain terminal, and a top gate terminal in the GaN wafer.

The GaN wafer may include a GaN channel and a first aluminum gallium nitride (AlGaN) layer. The GaN channel and the first AlGaN layer may be hydrogen cut and bonded to the pSiC substrate. According to various examples, the GaN channel may be a dual channel (shown as dashed lines) conducting current from a source terminal to a drain terminal. The GaN channel may be a single crystal, and the first AlGaN layer may be a single crystal layer. As discussed in connection with FIG. 2, the method may include forming a second AlGaN layer on a side of the GaN channel opposite the first AlGaN layer. The method may include forming a first insulator layer on the second AlGaN layer, forming an aluminum oxide (AlO) layer on the first insulator layer, and forming a second insulator layer on the AlO layer. The method may include forming a top gate terminal in the AlO layer.

The method may include forming a liner to line the mandrel opening in the first side of the pSiC substrate 510. According to various examples, the liner may be made of nickel (Ni) or titanium (Ti). The method may include inserting a metal paste into the mandrel opening in the first side of the pSiC substrate 512. For example, the metal paste may be made of one or more of silver, tin, or copper, and may be inserted using a squeegee process.

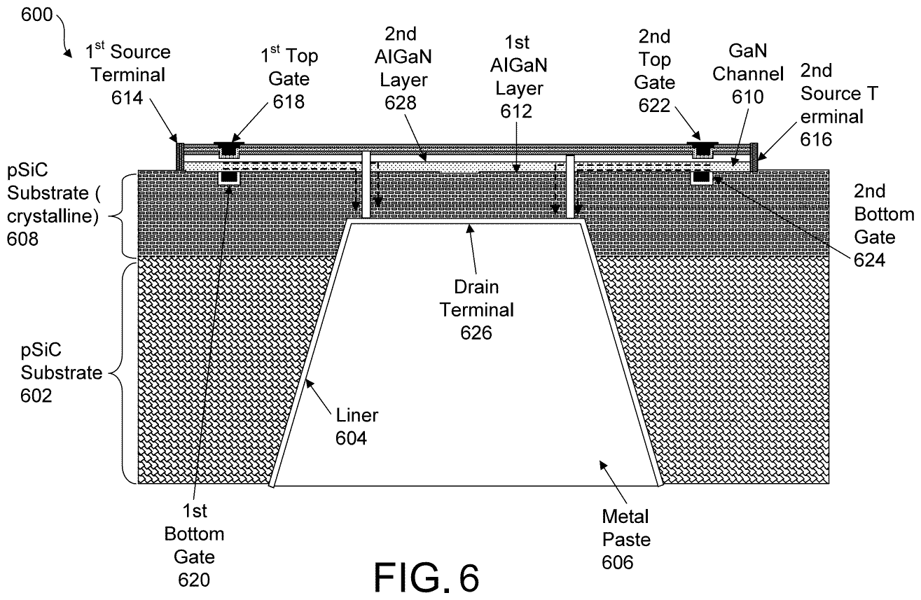

FIG. 6 shows a vertical semiconductor device 600 according to various examples. The vertical semiconductor device 600 according to various examples may include a pSiC substrate 602 bonded to a GaN wafer. The vertical semiconductor device 600 may include a mandrel opening at a first side of the pSiC substrate 602, which may include a liner 604 formed along the edge of the mandrel opening, and may be filled with a metal paste 606, as described in connection with FIG. 5 above. The pSiC substrate 602 may include a crystalline portion 608 that may be formed by a hot press process, as described above.

The GaN wafer may include a GaN channel 610, which may be a dual GaN channel that allows current to flow along two paths within the GaN channel, as indicated by the dashed arrows. The GaN wafer may also include a first AlGaN layer 612 between the GaN channel 610 and the pSiC substrate 602, which may be used as a seed layer to form the crystalline portion 608 of the pSiC substrate. The GaN wafer may also include a second AlGaN layer 628 on a side of the GaN channel 610 opposite the first AlGaN layer 612. The vertical semiconductor device 600 may include a first source terminal 614 and a second source terminal 616, which may be located at laterally opposite sides of the device. The vertical semiconductor device 600 may include a first top gate terminal 618 and a first bottom gate terminal 620 to control the flow of current from the first source terminal 614. The vertical semiconductor device 600 may include a second top gate terminal 622 and a second bottom gate terminal 624 to control the flow of current from the second source terminal 616. A drain terminal 626 may be formed at the bottom of the mandrel opening (i.e., the portion of the mandrel opening closest to the GaN channel 610). In this configuration, the crystalline portion 608 of the pSiC substrate functions as vertical drift region to facilitate current flow from the first 614 and second source terminals 616 to the drain terminal 626. According to various examples, the vertical semiconductor device 600 may be used at high voltages, and may lower the parasitic capacitance between the first 614 and second source terminals 616 and the drain terminal 626. By using a pSiC substrate 602 instead of single crystal substrate, cost may be reduced, and Eddy currents may be limited. In addition, the dual gate structure according to various examples may provide twice the current using the same amount of area as a single gate HEMT.

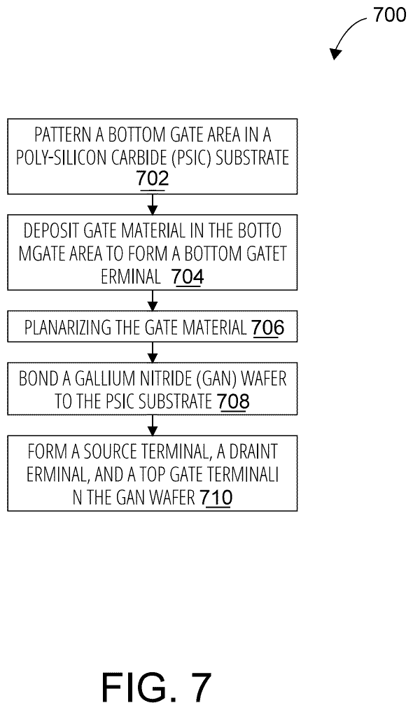

FIG. 7 shows a method of forming a semiconductor device according to various examples. It is to be appreciated that more or fewer operations than those shown in FIG. 7 may be performed. Further, some of the operations can be performed simultaneously, or in a different order than shown in FIG. 7, as will be understood by a person of ordinary skill in the art.

In operation 702, method 700 patterns a bottom gate area in a poly-silicon carbide (pSiC) substrate. In operation 704, method 700 deposits gate material in the bottom gate area to form a bottom gate terminal. In operation 706, method 700 planarizes the gate material. In operation 708, method 700 bonds a gallium nitride (GaN) wafer to the pSiC substrate. In operation 710, method 700 forms a source terminal, a drain terminal, and a top gate terminal in the GaN wafer.

Method 700 may include depositing an insulator material in the bottom gate area before depositing the gate material. The GaN wafer may include a dual GaN channel formed on a first aluminum gallium nitride (AlGaN) layer. The dual GaN channel may be a single crystal layer, and the first AlGaN layer may be a single crystal layer.

Method 700 may include forming a second AlGaN layer on a side of the dual GaN channel opposite the first AlGaN layer, forming a first insulator layer on the second AlGaN layer, forming an aluminum oxide (AlO) layer on the first insulator layer, and forming a second insulator layer on the AlO layer. The top gate terminal may be formed in contact with the AlO layer. The method may include performing a hot press process after the GaN wafer is bonded to the pSiC substrate to cause crystallization of at least a portion of the pSiC substrate.

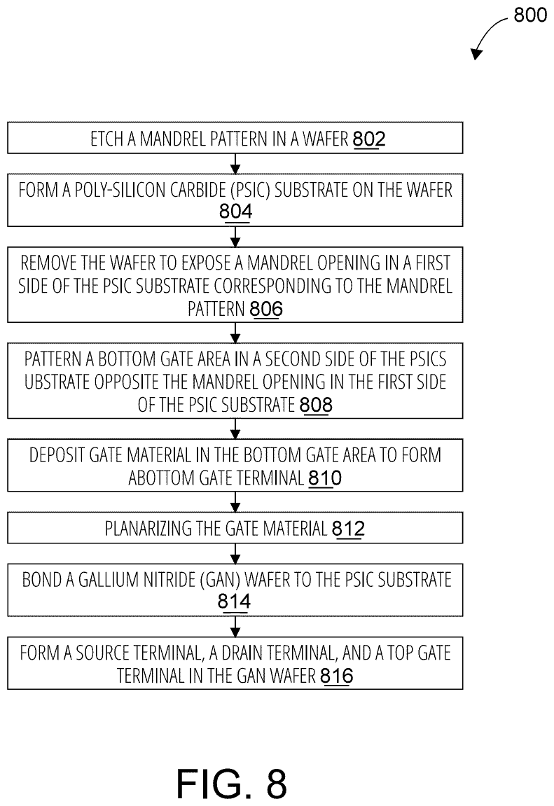

FIG. 8 shows a method of forming a semiconductor device according to various examples. It is to be appreciated that more or fewer operations than those shown in FIG. 8 may be performed. Further, some of the operations can be performed simultaneously, or in a different order than shown in FIG. 8, as will be understood by a person of ordinary skill in the art.

In operation 802, method 800 etches a mandrel pattern in a wafer. In operation 804, method 800 forms a poly-silicon carbide (pSiC) substrate on the wafer. In operation 806, method 800 removes the wafer to expose a mandrel opening in a first side of the pSiC substrate corresponding to the mandrel pattern. In operation 808, method 800 patterns a bottom gate area in a second side of the pSiC substrate opposite the mandrel opening in the first side of the pSiC substrate. In operation 810, method 800 deposits gate material in the bottom gate area to form a bottom gate terminal. In operation 812, method 800 planarizes the gate material. In operation 814, method 800 bonds a gallium nitride (GaN) wafer to the pSiC substrate. In operation 816, method 800 forms a source terminal, a drain terminal, and a top gate terminal in the GaN wafer.

Method 800 may include forming a liner to line the mandrel opening in the first side of the pSiC substrate. The liner may be made of nickel or titanium. Method 800 may include inserting a metal paste into the mandrel opening in the first side of the pSiC substrate. The GaN wafer may include a dual GaN channel formed on a first AlGaN layer. The dual GaN channel may be a single crystal layer, and the first AlGaN layer may be a single crystal layer. Method 800 may include forming the pSiC substrate by performing a hot press process on first AlGaN layer bonded to a pSiC substrate to cause crystallization of at least a portion of the pSiC substrate.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of these examples herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method of forming a semiconductor device, the method comprising:
patterning a bottom gate area in a poly-silicon carbide (pSiC) substrate;
depositing gate material in the bottom gate area to form a bottom gate terminal;
planarizing the gate material;
bonding a gallium nitride (GaN) wafer to the pSiC substrate; and
forming a source terminal, a drain terminal, and a top gate terminal in the GaN wafer.

2. The method of claim 1, comprising depositing an insulator material in the bottom gate area before depositing the gate material.

3. The method of claim 1, wherein the GaN wafer comprises a dual GaN channel formed on a first aluminum gallium nitride (AlGaN) layer.

4. The method of claim 3, wherein the dual GaN channel is a single crystal layer, and the first AlGaN layer is a single crystal layer.

5. The method of claim 3, comprising:
forming a second AlGaN layer on a side of the dual GaN channel opposite the first AlGaN layer;
forming a first insulator layer on the second AlGaN layer;
forming an aluminum oxide (AlO) layer on the first insulator layer; and
forming a second insulator layer on the AlO layer,
wherein the top gate terminal is formed in contact with the AlO layer.

6. The method of claim 1, comprising:
performing a hot press process after the GaN wafer is bonded to the pSiC substrate to cause crystallization of at least a portion of the pSiC substrate.

7. A method of forming a semiconductor device, the method comprising:
etching a mandrel pattern in a wafer;
forming a poly-silicon carbide (pSiC) substrate on the wafer;
removing the wafer to expose a mandrel opening in a first side of the pSiC substrate corresponding to the mandrel pattern;
patterning a bottom gate area in a second side of the pSiC substrate opposite the mandrel opening in the first side of the pSiC substrate;
depositing gate material in the bottom gate area to form a bottom gate terminal;
planarizing the gate material;
bonding a gallium nitride (GaN) wafer to the pSiC substrate; and
forming a source terminal, a drain terminal, and a top gate terminal in the GaN wafer.

8. The method of claim 7, comprising forming a liner to line the mandrel opening in the first side of the pSiC substrate.

9. The method of claim 8, wherein the liner is made of nickel or titanium.

10. The method of claim 8, comprising inserting a metal paste into the mandrel opening in the first side of the pSiC substrate.

11. The method of claim 7, wherein the GaN wafer comprises a dual GaN channel formed on a first aluminum gallium nitride (AlGaN) layer.

12. The method of claim 11, wherein the dual GaN channel is a single crystal layer, and the first AlGaN layer is a single crystal layer.

13. The method of claim 11, comprising forming the pSiC substrate by performing a hot press process on the first AlGaN layer bonded to the pSiC substrate to cause crystallization of at least a portion of the pSiC substrate.

14. A semiconductor device comprising:
a poly-silicon carbide (pSiC) substrate having a bottom gate terminal in a first side of the pSiC substrate; and
a gallium nitride (GaN) wafer in contact with the pSiC substrate,
wherein the GaN wafer includes a source terminal, a drain terminal, and a top gate terminal.

15. The semiconductor device of claim 14, wherein the GaN wafer comprises a dual GaN channel in contact with a first aluminum gallium nitride (AlGaN) layer.

16. The semiconductor device of claim 15, wherein the dual GaN channel is a single crystal layer, and the first AlGaN layer is a single crystal layer.

17. The semiconductor device of claim 14, wherein the pSiC substrate includes a crystallized portion adjacent to the GaN wafer.

18. The semiconductor device of claim 14, comprising a mandrel opening in a second side of the PSiC substrate opposite the bottom gate terminal.

19. The semiconductor device of claim 18, comprising a metal paste within the mandrel opening.

20. The semiconductor device of claim 19, comprising a liner to line the mandrel opening.
